(19) United States
(12) Patent Application Publication
(10) Pub. No.: US 2021/0126423 A1
(43) Pub. Date: Apr. 29, 2021

(54) LASER DIODE PACKAGING STRUCTURE AND LIGHT SOURCE MODULE INCLUDING THE SAME

(71) Applicant: QUANZHOU SANAN SEMICONDUCTOR TECHNOLOGY CO., LTD, Nanan City (CN)

(72) Inventors: Hui CHEN, Xiamen (CN); Junpeng SHI, Xiamen (CN); Chi-Wei LIAO, Xiamen (CN); Weng-Tack WONG, Xiamen (CN); Chen-ke HSU, Xiamen (CN)

(21) Appl. No.: 17/139,230

(22) Filed: Dec. 31, 2020

Related U.S. Application Data
(63) Continuation-in-part of application No. PCT/CN2018/125438, filed on Dec. 29, 2018.

(51) Int. Cl. H01S 5/0235; H01S 5/0232; H01S 5/042; H01S 5/0233; H01S 5/40

(52) U.S. Cl. CPC H01S 5/0235; H01S 5/0232; H01S 5/4025; H01S 5/0233; H01S 5/04256

(57) ABSTRACT

A laser diode packaging structure includes a lead frame and a laser chip. The lead frame includes a frame body that has a front side and a back side opposite to the front side, a front circuit layer and a back circuit layer that are respectively disposed on the front and back sides, and an inner circuit layer that is disposed inside the frame body. The inner circuit layer includes first and second circuit connecting units, each of which has at least one first conductive via to electrically connect to the front circuit layer, and at least one second conductive via to electrically connect to the back circuit layer. The laser chip is mounted on and electrically connected to the front circuit layer, and is configured to emit a laser beam.

### CROSS-REFERENCE TO RELATED APPLICATION

This application is a bypass continuation-in-part application of PCT International Application No. PCT/CN2018/125438 filed on Dec. 29, 2018. The entire content of the international patent application is incorporated herein by reference.

### FIELD

The disclosure relates to a laser diode, and more particularly to a high power laser diode packaging structure.

### BACKGROUND

Since a semiconductor laser diode (LD) has a good monochromaticity, small size, long service life, high power density, and high speed operation, such semiconductor laser diode is widely applied in various fields such as laser rangefinder, laser radar, laser communication, laser simulation weapon, automatic control, and detection instrument. However, there is still a need to enhance the power of the semiconductor laser diode.

### SUMMARY

Therefore, an object of the disclosure is to provide a laser diode packaging structure and a light source module that can alleviate or eliminate at least one of the drawbacks of the prior art.

According to the disclosure, the laser diode packaging structure includes a lead frame and at least one laser chip.

The lead frame includes a frame body that has a front side and a back side opposite to the front side, a front circuit layer and a back circuit layer that are respectively disposed on the front and back sides, and an inner circuit layer that is disposed inside the frame body. The inner circuit layer includes a first circuit connecting unit and a second connecting unit. Each of the first and second circuit connecting units has at least one first conductive via to electrically connect to the front circuit layer, and at least one second conductive via to electrically connect to the back circuit layer.

The laser chip is mounted on and electrically connected to the front circuit layer, and is configured to emit a laser beam.

According to the disclosure, the light source module includes the laser diode packaging structure as mentioned above.

### BRIEF DESCRIPTION OF THE DRAWINGS

Other features and advantages of the disclosure will become apparent in the following detailed description of the embodiments with reference to the accompanying drawings, of which:

FIG. 1 is a sectional view illustrating a first embodiment of a laser diode packaging structure according to the disclosure;

FIG. 2 is a schematic top view illustrating the first embodiment according to the disclosure;

FIG. 3 is a schematic view illustrating an inner circuit layer of the first embodiment according to the disclosure;

FIG. 4 is a schematic view illustrating a back circuit layer of the first embodiment according to the disclosure;

FIG. 5 is a cross-sectional view illustrating the first embodiment which is mounted on a printed circuit board;

FIG. 6 is a schematic top view illustrating a second embodiment of the laser diode packaging structure according to the disclosure;

FIG. 7 is a schematic view illustrating a back circuit layer of the second embodiment according to the disclosure;

FIG. 8 is a schematic view illustrating an inner circuit layer of the second embodiment according to the disclosure;

FIG. 9 is a schematic view illustrating a third embodiment of the laser diode packaging structure according to the disclosure;

FIG. 10 is a schematic view illustrating an inner circuit layer of the third embodiment according to the disclosure;

FIG. 11 is a schematic top view illustrating a fourth embodiment of the laser diode packaging structure according to the disclosure;

FIG. 12 is a schematic view illustrating an inner circuit layer of the fourth embodiment according to the disclosure;

FIG. 13 is a cross-sectional view illustrating a fifth embodiment of the laser diode packaging structure according to the disclosure;

FIG. 14 is a top view illustrating a configuration of a wavelength conversion layer of the fifth embodiment of FIG. 13;

FIG. 15 is a top view illustrating another configuration of the wavelength conversion layer of the fifth embodiment;

FIG. 16 is a cross-sectional view illustrating a variation of the fifth embodiment according to the disclosure;

FIG. 17 is a cross-sectional view illustrating a sixth embodiment of the laser diode packaging structure according to the disclosure; and

FIG. 18 is a schematic view illustrating a light source module that includes the laser diode packaging structure according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted that, directional terms, such as “vertical,” “horizontal,” “top,” “bottom,” “upper,” “lower,” “inner,” “inwardly,” “outer,” and “outwardly,” “front,” “rear,” “left,” “right”, “top” and “bottom,” may be used to assist in describing the disclosure based on the orientation of the embodiments shown in the figures. The use of these directional definitions should not be interpreted to limit the disclosure in any way.

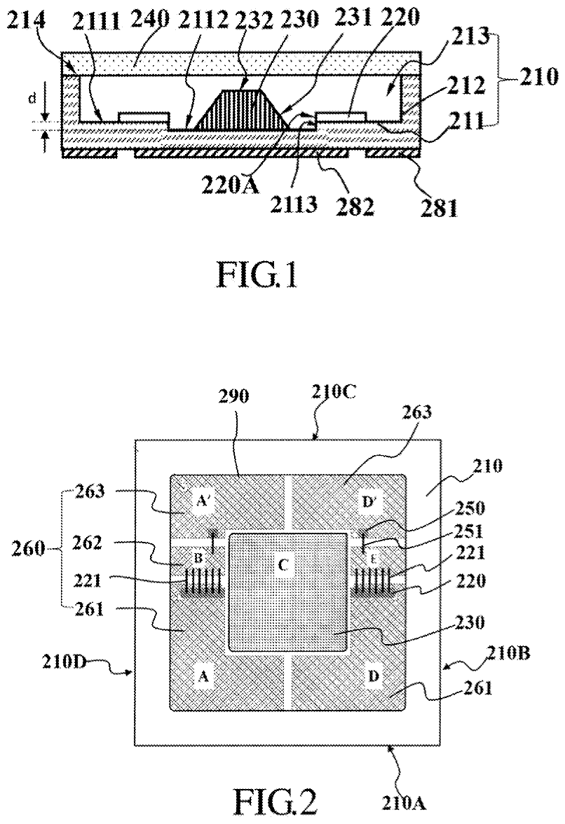

Referring to FIGS. 1 to 4, a first embodiment of a laser diode packaging structure according to the present disclosure includes a lead frame 210, at least one laser chip 220, an optical element 230, and a cover plate 240.

The lead frame 210 includes a frame body that has a front side and a back side opposite to the front side, a front circuit layer 290 and a back circuit layer 280 that are respectively disposed on the front and back sides, and an inner circuit layer 270 that is disposed inside the frame body. The laser chip 220 is mounted on and electrically connected to the front circuit layer 290, and is configured to emit a laser beam.

The frame body of the lead frame 210 may have a cup structure. That is, the frame body is formed with a recess 213 defined by a recess-defining wall. The recess-defining wall includes a bottom surface 211, and a surrounding surface 212 extending upwardly from the bottom surface 211. In this embodiment, the bottom surface 211 has a stepped structure, which includes an upper part 2111, a lower part 2112, and a connecting part 2113 interconnecting the upper part 2111 and the lower part 2112. A height (D) measured from the lower part 2112 to the upper part 2111 may range from 0.1 mm to 0.5 mm (such as 0.1 mm to 0.3 mm). There are no particular limitations on the material for making the lead frame 210. In this embodiment, the lead frame 210 is made of a ceramic material with a high thermal conductivity, such as Al₂O₃ or AlN.

The recess-defining wall may have a rectangular cross section. That is, the bottom surface 211 of the frame body includes four edge portions 210A˜210D, a center region C and a peripheral region which is located between the four edge portions 210A˜210D and the center region C. The center region C may be located at the lower part 2112, and the peripheral region may be located at the upper part 2111. In this embodiment, the laser diode packaging structure includes two laser chips 220 which are mounted distal from the optical element 230, e.g., on the peripheral region (i.e., the upper part 2111 of the bottom surface 211).

Each of the laser chips 220 has a light-emitting side surface 220A which may be arranged vertically in line with the connecting part 2113 of the bottom portion 211. Alternatively, each of the laser chips 220 may laterally protrude beyond the connecting part 2113, so as to reduce an amount of laser beam which is emitted from the laser chips 220 and which is being transmitted to the bottom surface 211 of the frame body.

The optical element 230 is mounted on the front circuit layer 290, e.g., the center region C of the frame body (i.e., the lower part 2112 of the bottom surface 211), and is configured to direct the laser beam emitted from the laser chip 220. For example, the laser beam incident on the optical element 230 may be directed and reflected by the optical element 230, and then may be emitted in a direction away from the bottom surface 211 (e.g., perpendicular to the bottom surface 211), so as to increase the light-emitting efficiency of the laser diode packaging structure according to this disclosure.

In certain embodiments, the optical element 230 includes an inclined side surface 231 which extends away from the bottom surface 211 of the frame body, and a top surface 232 which is connected to the inclined side surface 231 and which has a platform adapted to be picked up by a nozzle device during a packaging process. The platform may have an area that is greater than 0.5 mm×0.5 mm. The inclined side surface 231 may be formed with a reflective structure having a relatively high reflectivity. Examples of a material for making the reflective structure may include, but are not limited to, a metal. (e.g., Ag, Al or Au), an oxide (e.g., SiO₂, TiO₂, MgF₂ or Al₂O₃), and a combination thereof. The inclined side surface 231 of the optical element 230 may have a plurality of the reflective structures with different shapes and/or different reflecting angles. In such case, the reflecting angle of each of the reflective structures may be adjusted according to practical requirements, so as to control the overlapping degree of faculae of the laser beams emitted from the laser chips 220, thereby achieving a variable light-emitting angle of the laser diode packaging structure.

The front circuit layer 290 of the lead frame 210 includes two mounting units 260 that are disposed on left and right sides of the upper part 2111 of the bottom surface 211, respectively. Each of the mounting units 260 has a first region 261 (denoted as A and D in FIG. 2), a second region 262 (denoted as B and E in FIG. 2), and a third region 263 (denoted as A′ and D′ in FIG. 2) that are electrically isolated from each other and that are individually coated with a conductive material. The first region 261 may have an area greater than a total area of the second region 262 and the third region 263.

In this embodiment, each of the laser chips 220 is mounted on the first region 261 (A and D) of a respective one of the mounting units 260, and is electrically connected to the second region 262 of the respective one of the mounting units 260 through lead wires 221.

The laser diode packaging structure may further include at least one anti-electrostatic discharge element 250 that is mounted on the third region 263 of one of the mounting units 260, and that is electrically connected to the second region 262 of the one of the mounting units 260 through at least one lead wire 251. For each of the mounting units 260, the first region 261 is electrically connected to the third region 263 through the inner circuit layer 270.

The inner circuit layer 270 includes one or more first circuit connecting units and one or more second circuit connecting units. In this embodiment, the inner circuit layer 270 includes two first circuit connecting units 271, 273 and two second circuit connecting units 272, 274. The first and second circuit connecting units 271, 272 cooperatively form a first pair of circuit connecting units, and the first and second circuit connecting units 273, 214 cooperatively form a second pair of circuit connecting units. The first and second pairs of the circuit connecting units are disposed in the left side and right side of the upper part 2111, and correspond in position to the two mounting units 260 of the front circuit layer 290. That is, each of the first and second circuit connecting units 271-274 of the inner circuit layer 270 is located outside of a projection of the optical element 230 on the inner circuit layer 270. Each of the first and second circuit connecting units 271-274 has at least one first conductive via (shown as “●” shown in the figures) to electrically connect to the front circuit layer 290, and at least one second conductive via (shown as “◯” shown in the figures) to electrically connect to the back circuit layer 280. The second conductive via may be farther to a geometric center of the inner circuit layer 270 than the first conductive via. Each of the first circuit connecting units 271, 273 may include a plurality of first conductive vias A1, C1 that are electrically connected to different regions of the front circuit layer 290. In addition, each of the first and second circuit connecting units 271-274 may have a terminal end portion 2711, 2721 that is adjacent to one of the four edge portions 210A-210D, and an extension portion 2712, 2722 that extends away from the terminal end portion 2711, 2721 towards another one of the four edge portions 210A-210D.

In this embodiment, for each of the first circuit connecting units 271, 273, a plurality of the second conductive vias B1 are located at the terminal end portion 2711 which is adjacent to the edge portion 210A of the bottom surface 211 of the frame body, and the first conductive vias A1, C1 are spaced apart from the second conductive vias B1 and are located at the extension portion 2712 which extends from the terminal end portion 2711 toward the edge portion 210C. Compared with the first conductive vias C1, the first conductive vias A1 are located closer to the second conductive vias B1. For example, the first conductive vias C1 may be located at a region of the extending portion 2712 that is far away from the terminal end portion 2711.

In addition, for each of the second circuit connecting units 272, 274, a plurality of the second conductive vias B2 are located at the terminal end portion 2721 which is adjacent to the edge portion 210C of the bottom surface 211, and the first conductive vias A2 are spaced apart from the second conductive vias B2 and are located at the extension portion 2722 which extends from the terminal end portion 2721 toward the edge portion 210A.

The first region 261 of each of the mounting units 260 is electrically connected to a respective one of the first circuit connecting units 271, 273 of the inner circuit layer 270. The second region 262 of each of the mounting units 260 is electrically connected to a respective one of the second circuit connecting units 272, 274 of the inner circuit layer 270. The third region 262 of each of the mounting units 260 is electrically connected to the first region 261 through the respective one of the first circuit connecting units 271, 273.

As shown in FIG. 4, the back circuit layer 280 includes a plurality of back electrodes 281 that are arranged on a peripheral region of the back surface of the frame body. The back circuit layer 280 may further include a heat dissipating electrode 282 that is disposed on a center region of the back surface of the frame body distal from the peripheral region. The back electrodes 281 may be disposed on two opposite sides of the heat dissipating electrode 282. In this embodiment, the heat dissipating electrode 282 is disposed on a center region P3, and four back electrodes 281 are respectively arranged on four peripheral regions P1, P2, P4, P5, in which the peripheral regions P1, P2 are spacedly located at one side (e.g., upper side) of the center region P3, and the peripheral regions P4, P5 are spacedly located at the other side (e.g., lower side) of the center region P3.

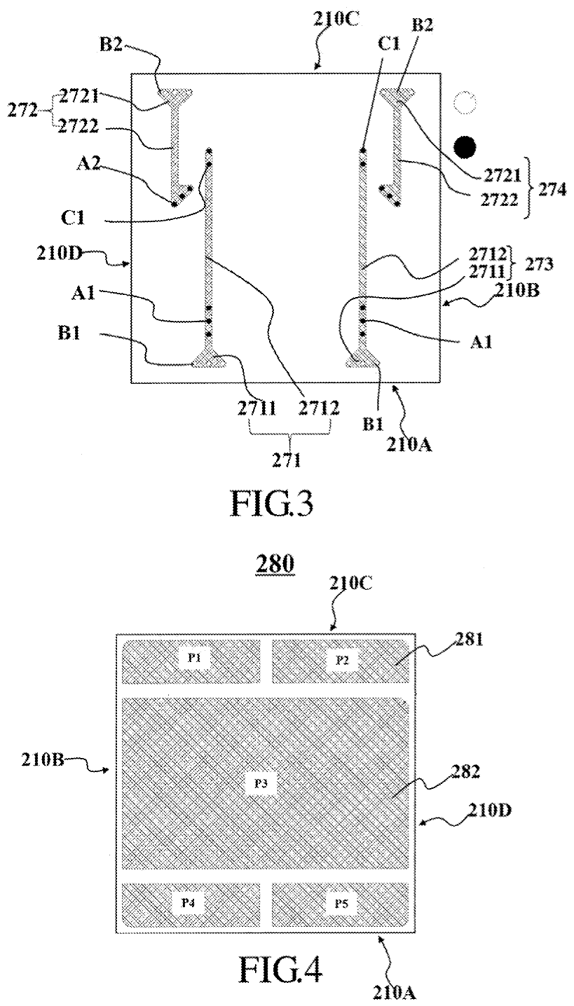

Referring back to FIG. 2, in combination with FIGS. 3 and 4, the electrical connection of the laser chips 220, the inner circuit layer 270, the front circuit layer 290 and the back circuit layer 280 in this embodiment are described in more details below. Specifically, each of the laser chips 220 is disposed on the first region 261 of the respective one of the mounting units 260, and is electrically connected to two of the first and second circuit connecting units 271-274 and two of the back electrodes 281. Each of the first circuit connecting units 271, 273 includes two groups of the first conductive vias A1, C1 and one group of the second conductive vias B1. The two groups of the first conductive vias A1, C1 are respectively electrically connected to the first region 261 (A and D) and the third region 263 (A and D′) on the front circuit layer 290, and the one group of the second conductive vias B1 is electrically connected to a portion of the back electrodes 281 on the back circuit layer 280. Each of the second circuit connecting units 272, 274 includes one group of the first conductive vias A2 and one group of the second conductive vias B2. The first conductive vias A2 and the second conductive vias B2 are electrically connected to the second region 262 on the front circuit layer 290 and the remaining back electrodes 281 on the back circuit layer 280, respectively. In addition, the first and third regions 261, 263 (A and A′) of one of the mounting units 260 are electrically connected to the peripheral region P, and the first and third regions 261, 263 (D and D′) of the other one of the mounting units 260 are electrically connected to the peripheral region P4. The second region 262 (B) of one of the mounting units 260 is electrically connected to the peripheral region P2, and the second region 262 (B′) of the other one of the mounting units 260 is electrically connected to the peripheral region P1. In other words, the laser chips 220 and the front circuit layer 290 can be electrically connected to the back electrodes 281 of the back circuit layer 280 through the first and second circuit connecting units 271, 272 of the inner circuit layer 270.

By virtue of the abovementioned circuit structure design of the lead frame 210, single or multiple laser chips 220 (along with the anti-electrostatic discharge element 250) can be packaged in the laser diode packaging structure of this disclosure. In addition, the laser chips 220 may be independently powered on or off according to practical requirements, so as to exhibit tunable optical properties.

The laser diode packaging structure may further include a cover plate 240 disposed on the surrounding surface 212 opposite to the bottom surface 211 of the frame body for sealing the laser chip 220 and the optical element 230 in the recess 213. A silica gel or an Au—Sn eutectic bonding may be used to adhere the cover plate 240 to the lead frame 210. Examples of a material for making the cover plate 240 may include, but are not limited to, glass, quartz, sapphire, and transparent ceramic.

In addition, according to different light color requirements, the cover plate 240 may include a wavelength conversion material, such as a phosphor in glass (PIG), a phosphor in ceramic (PIC), single crystal phosphor, or the like. Such wavelength conversion material may have a thermal conductivity that is greater than 10 W/(m·k). The light (e.g., a laser beam) exiting from such wavelength conversion material may have a light-emitting angle that is lower than 90°, and has a maximum light intensity in a direction perpendicular to the frame body (i.e., the normal direction). Moreover, since light passing through such wavelength conversion material may generate heat energy caused by stokes shift and wavelength conversion efficiency, the surrounding surface 212 of the frame body with a high thermal conductivity may serve as a heat dissipating medium for such wavelength conversion material. In certain embodiments, the cover plate 240 may be bonded to the lead frame 210 using a high thermal conductive bonding technique, such as surface activated bonding (SAB) technique or atomic diffusion bonding (ADB) technique. In other embodiments, the cover plate 240 may be bonded to the lead frame 210 through a transparent material with a high thermal conductivity of greater than 1 W/(m·k). It should be noted that although the cover plate 240 is used in this embodiment, the recess 213 may be filled with a silica gel, so as to encapsulate and protect the laser chip 220 and the optical element 230.

The laser diode packaging structure may further include a heat dissipating electrode 282 disposed on the center region P3 of the back circuit layer 280 to achieve thermoelectric separation. Referring to FIG. 5, the laser diode packaging structure of this disclosure may be mounted on a printed circuit board (PCB) 100 or a heat sink metal substrate through the center region P3 of the back circuit layer 280, which is conducive to fast heat dissipation of the laser diode packaging structure. The printed circuit board (PCB) 100 may include a PCB body 110, a protruding portion 111, a soldering layer 121, a circuit layer 122, a solder resistant layer 123, and an insulating layer 124.

Specifically, the protruding portion 111 protrudes upwardly from a center region of the PCB body 110. The insulating layer 124 and the circuit layer 122 are sequentially disposed on a peripheral region of the PCB body 110. The soldering layer 121 is disposed on the protruding portion 111 and a portion of the circuit layer 122. The solder resistant layer 123 is disposed on a remaining portion of the circuit layer 122, and is adjacent to the soldering layer 121. The protruding portion 111 and the circuit layer 122 are respectively connected to the heat dissipating electrode 282 and the back electrodes 281 through the soldering layer 121.

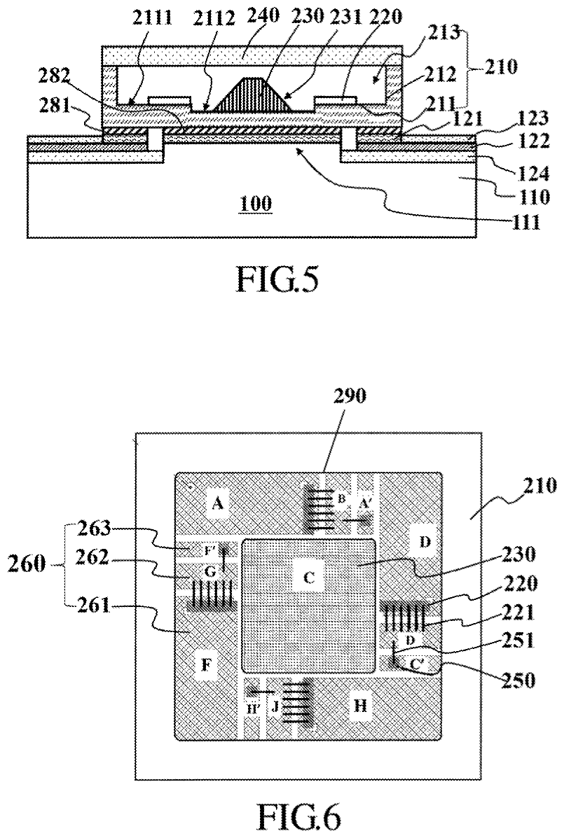

Referring to FIGS. 6 to 8, a second embodiment of the laser diode packaging structure is generally similar to the first embodiment, except that in the second embodiment, the laser diode packaging structure includes four laser chips 220 and four anti-electrostatic discharge elements 250, the front circuit layer 290 includes four mounting units 260 (first to fourth mounting units 260), the inner circuit layer 270 includes four pairs of circuit connecting units (i.e., four of the first circuit connecting units 271, 273, 275, 277 and four of the second circuit connecting units 272, 274, 276, 278), and the back circuit layer 280 includes eight peripheral regions.

Specifically, a first pair of the first and second circuit connecting units 271, 272 are electrically connected to the first to third regions (denoted as A, B, A′) of the first mounting unit 260. A second pair of the first and second circuit connecting units 273, 274 are electrically connected to the first to third regions (denoted as C, D, C′) of the second mounting unit 260. A third pair of the first and second circuit connecting units 275, 276 are electrically connected to the first to third regions (denoted as H, J, H′) of the third mounting unit 260. A fourth pair of the first and second circuit connecting units 277, 278 are electrically connected to the first to third regions (denoted as F, G, F′) of the fourth mounting unit 260.

Each of the four laser chips 220 is mounted on a respective one of the first regions 261 (A, C, H and F), and is electrically connected to a respective one of the second regions 262 (B, D, J and G) through the lead wires 221. Each of the anti-electrostatic discharge elements 250 is mounted on a respective one of the third regions 263 (A′, C′, H′ and F′), and is electrically connected to a respective one of the second regions 262 (B, D, J and G) through at least one of the lead wires 251. The four first regions 260 (A, C, F and H) are respectively electrically connected to the four third regions 263 (A′, C′, F′ and H′) through the inner circuit layer 270.

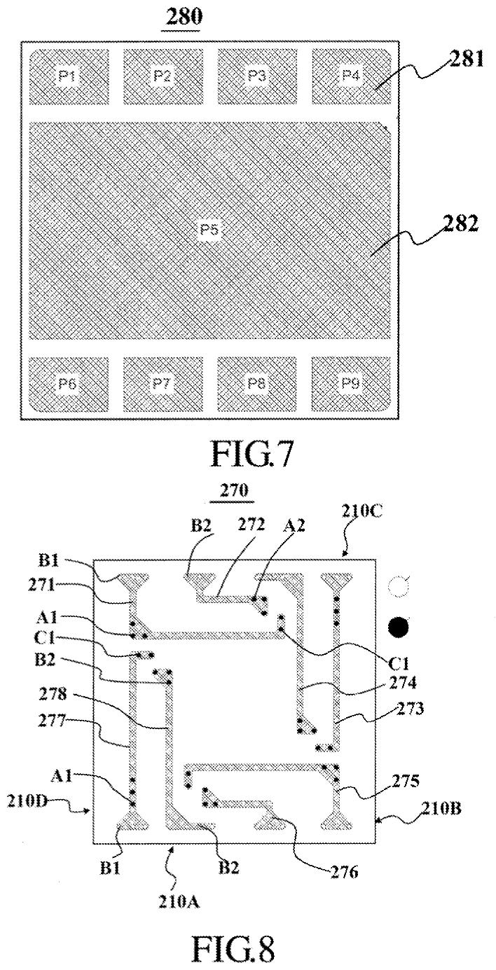

Referring again to FIG. 6, in combination with FIG. 7, the electrical connection between the front circuit layer 290 and the back circuit layer 280 is described as follows.

For the first mounting unit 260, the first and third regions 261, 263 (A and A′) are electrically connected to the peripheral region P4, and the second region 262 (B) is electrically connected to the peripheral region P3. For the second mounting unit 260, the first and third regions 261, 263 (C and C′) are electrically connected to the peripheral region P1, and the second region 262 (D) is electrically connected to the peripheral region P2. For the third mounting unit 260, the first and third regions 261, 263 (F and F′) are electrically connected to the peripheral region P9, and the second region 262 (G) is electrically connected to the peripheral region P8. For the fourth mounting unit 260, the first and third regions 261, 263 (H and H′) are electrically connected to the peripheral region P6, and the second region 262 (J) is electrically connected to the peripheral region P7.

The heat dissipating electrode 282 is disposed on the center region P5 of the back circuit layer 280. The optical element 230 is disposed on the center region E of the front circuit layer 290.

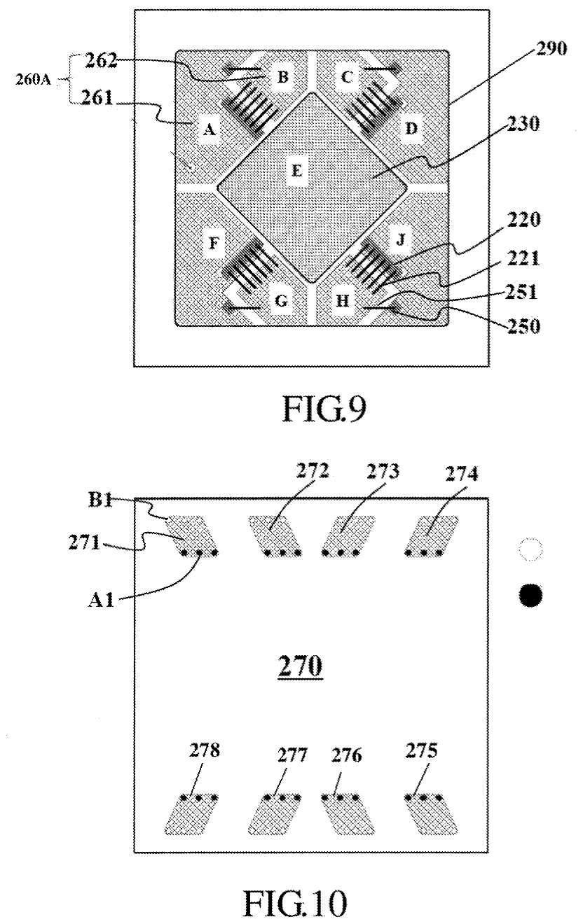

Referring to FIGS. 9 and 10, a third embodiment of the laser diode packaging structure is generally similar to the second embodiment, except for the following differences.

Specifically, each of the first to fourth mounting units 260 only includes one first region 261 (denoted as A, D, J and F) and one second region 262 (denoted as B, C, H and G). Each of the laser chips 220 may be located adjacent to a diagonal line of the rectangular cross section of the recess-defining wall. In this embodiment, two of the laser chips 220 are located at one of the diagonal lines of the rectangular cross section of the recess-defining wall, and the remaining laser chips 220 are located at the other one of the diagonal lines of the rectangular cross section of the recess-defining wall. Each of the four laser chips 220 is mounted on a respective one of the first regions 261 (A, D, J and F), and is electrically connected to a respective one of the second regions 262 (B, C, H, and G) through the lead wires 221. Each of the anti-electrostatic discharge elements 250 is mounted on a respective one of the first regions 261 (A, D, J and F), and is electrically connected to a respective one of the second regions 262 (B, C, H and G) through at least one of the lead wires 251.

In addition, the first and second pairs of the circuit connecting units 271˜274 are disposed on a first side (e.g., upper side) of the peripheral region of the frame body, and the third and fourth pairs of the circuit connecting units 275˜278 are disposed on a second side (e.g., lower side) of the peripheral region opposite to the first side. Each of the first and second circuit connecting units 271˜278 has a parallelogram shape. Each of the first circuit connecting units 271, 273, 275, 277 includes one group of the first conductive vias A1 to electrically connect to the front circuit layer 290, and one group of the second conductive vias B1 to electrically connect to the back circuit layer 280. Each of the second circuit connecting units 272, 274, 276, 278 includes one group of the first conductive vias A2 to electrically connect to the front circuit layer 290, and one group of the second conductive vias B2 to electrically connect to the back circuit layer 280.

Referring again to FIG. 7, in combination with FIG. 9, the electrical connection between the front circuit layer 290 and the back circuit layer 280 is described as follows.

For the first mounting unit 260, the first region 261 (A) is electrically connected to the peripheral region P4, and the second region 262 (B) is electrically connected to the peripheral region P3. For the second mounting unit 260, the first region 261 (D) is electrically connected to the peripheral region P1, and the second region 262 (C) is electrically connected to the peripheral region P2. For the third mounting unit 260, the first region 261 (J) is electrically connected to the peripheral region P6, and the second region 262 (H) is electrically connected to the peripheral region P7. For the fourth mounting unit 260, the first region 261 (F) is electrically connected to the peripheral region P9, and the second region 262 (G) is electrically connected to the peripheral region P8.

In such case, the dimension of the laser diode packaging structure can be decreased to a certain extent, and the design of inner circuit layer 270 can be simplified, so as to enhance the reliability of the laser diode packaging structure.

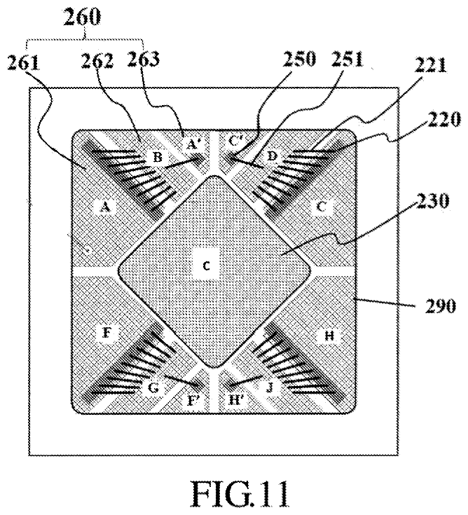

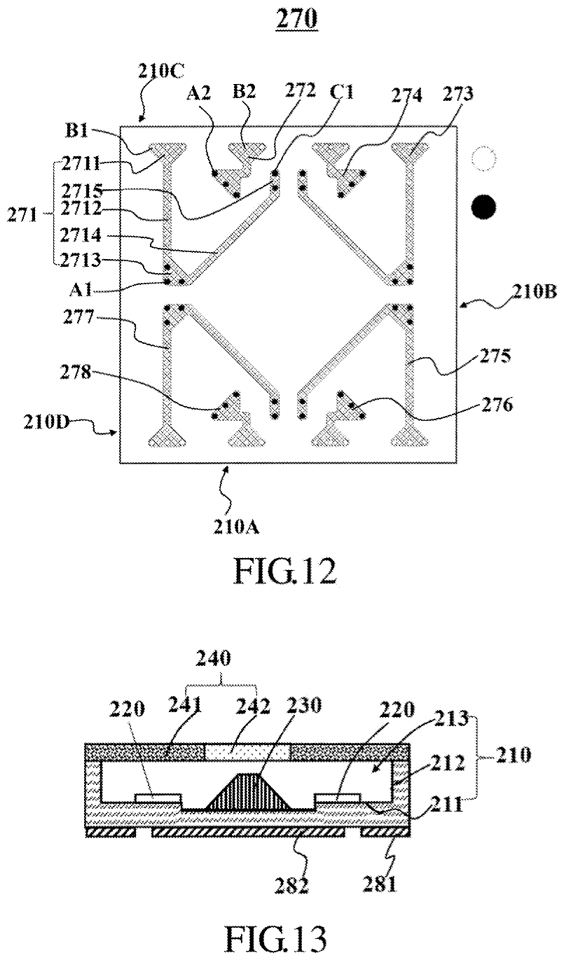

Referring to FIGS. 11 and 12, a fourth embodiment of the laser diode packaging structure is generally similar to the third embodiment, except for the configuration of the front circuit layer 290 and the inner circuit layer 270.

Specifically, each of the first to fourth mounting units 260 on the front circuit layer 290 further includes a third region 263 (denoted as A′, C′, H′ and F′) that is electrically isolated from the first and second regions 261, 262, and each of the four anti-electrostatic discharge elements 250 are mounted on the third region 263 of a respective one of the first to fourth mounting units 260.

In addition, with respect to the inner circuit layer 270, each of the first circuit connecting units 271, 273, 275, 277 includes a first terminal end portion 2711, a first extension portion 2712, a connecting portion 2713, a second extension portion 2714, and a second terminal end portion 2715. The first terminal end portion 2711 is adjacent to one of the edge portions 210D, 210C. The first extension portion 2712 extends away from the first terminal end portion 2711, and connects to the connecting portion 2713. The second extension portion 2714 extends away from the connecting portion 2713, and connects to the second terminal end portion 2715 that is opposite to the first terminal end portion 2711. Each of the first circuit connecting units 271, 273, 275, 277 includes two groups of the first conductive vias A1, C1 and one group of the second conductive vias B1. The two groups of the first conductive vias A1, C1 are respectively electrically connected to the first region 261 (A, C, H and F) and the third region 263 (A′, C′, H′ and F′) on the front circuit layer 290. The one group of the second conductive vias B1 is electrically connected to a portion of the back electrodes 281 on the back circuit layer 280. Each of the second conductive vias B1 is located at the first terminal end portion 2711, and the first conductive vias A1, C1 are located at the connecting portion 2713 and the second terminal end portion 2715, respectively.

Referring back to FIGS. 7 and 11, the electrical connection between the front circuit layer 290 and the back circuit layer 280 is described as follows.

For the first mounting unit 260, the first and third regions 261, 263 (A and A′) are electrically connected to the peripheral region P4, and the second region 262 (B) is electrically connected to the peripheral region P3. For the second mounting unit 260, the first and third regions 261, 263 (C and C′) are electrically connected to the peripheral region P1, and the second region 262 (D) is electrically connected to the peripheral region P2. For the third mounting unit 260, the first and third regions 261, 263 (F and F′) are electrically connected to the peripheral region P9, and the second region 262 (G) is electrically connected to the peripheral region P8. For the fourth mounting unit 260, the first and third regions 261, 263 (H and H′) are electrically connected to the peripheral region P6, and the second region 262 (J) is electrically connected to the peripheral region P7.

By virtue of the circuit structure design of this embodiment, a packaging size of the laser diode packaging structure can be further reduced or the laser chips with a larger dimension can be mounted thereon.

It should be noted that the configuration for each of the front circuit layer 290, the back circuit layer 280, and the inner circuit layer 270 is not limited to those described above, and may vary depending on the structure of the lead frame 210, and/or the size and number of the laser chips 220, so as to meet practical requirements.

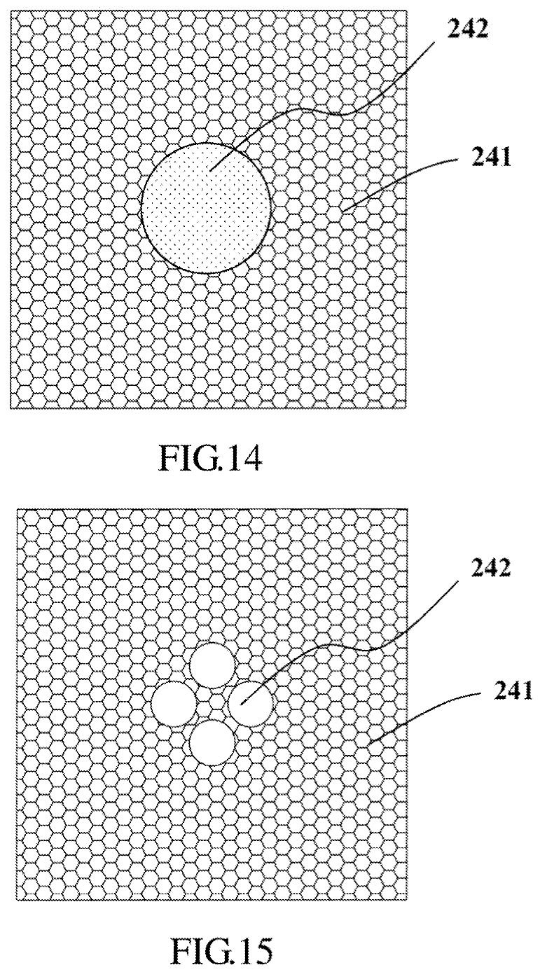

Referring to FIGS. 13 and 14, a fifth embodiment of the laser diode packaging structure is generally similar to the first embodiment, except that in the fifth embodiment, the cover plate 240 includes a plate body 241 made of a metallic material, and a wavelength conversion layer 242 containing a wavelength conversion material. The plate body 241 may be formed with at least one opening, and the wavelength conversion layer connects to the plate body 241 and fittingly fills the opening. Alternatively, the plate body 241 may have a plurality of the openings (shown in FIG. 15) according to a facula shape of the laser beam to be formed.

In this embodiment, the opening of the plate body 241 corresponds in position to the optical element 230, so as to decrease the light-emitting angle of the laser diode packaging structure. In addition, the metallic material of the plate body 241 with a high thermal conductivity is conducive to dissipation of heat generated from the wavelength conversion layer 242 during the wavelength conversion process.

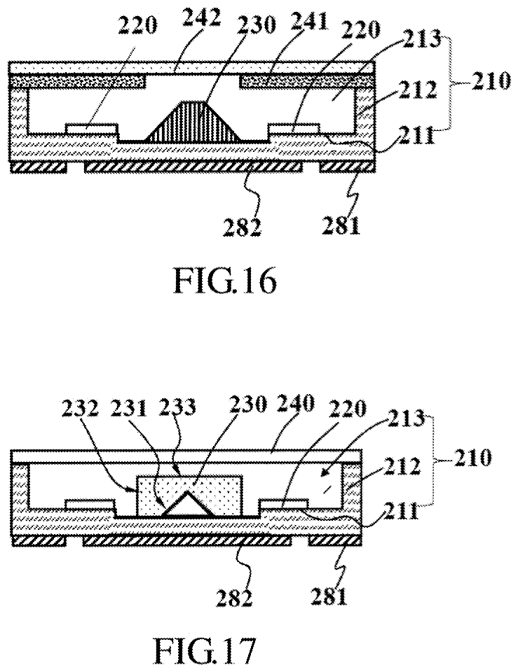

Referring to FIG. 16, in a variation of the fifth embodiment, the wavelength conversion layer 242 is disposed on the plate body 241, so as to increase a contact area between the wavelength conversion layer 242 and the plate body 241, thereby further enhancing a heat dissipation function of the cover plate 240.

Referring to FIG. 17, a sixth embodiment of the laser diode packaging structure is generally similar to the first embodiment, except that in the sixth embodiment, the optical element 230 is a prism with a high reflectivity which includes the inclined side surface 231, a light incident surface 232, and a light emitting surface 233. The wavelength conversion layer 242 as mentioned in the fifth embodiment may be disposed on the light incident surface 232 and/or the light emitting surface 233. The optical element 230 may be made of a material with a transmittance of greater than 80% at a thickness of 1 mm and a high thermal conductivity of greater than 5 W/(m·k). Examples of a material for making the optical element 230 may include, but are not limited to, a high thermal conductivity glass, a silicon dioxide, a sapphire, a transparent ceramic, and combinations thereof.

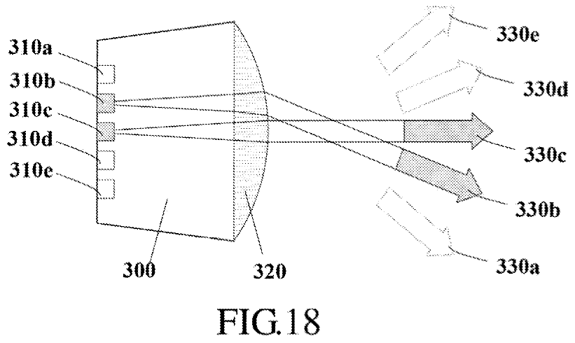

FIG. 18 shows a light source module 300 that includes the laser diode packaging structure of this disclosure for providing a light with reduced light emitting angle which is more capable of illuminating a designated area. As such, the light source module 300 is adapted for use in highly directional lighting devices or telecommunication devices, such as a headlight, a high bay light, a fishing lamp, a nautical light, a projecting apparatus, a laser TV, or an optical communication device. As shown in FIG. 18, the light source module 300 includes a plurality of laser sources 310a, 310b, 310c, 310d, 310e arranged in a matrix and a lens 320. Each of the laser sources 310a, 310b, 310c, 310d, 310e can be independently powered on or off through a predetermined circuit design. The light emitted from each of the laser sources 310a, 310b, 310c, 310d, 310e can pass through the lens 320 or a reflector (not shown in the figures), and then illuminates a predetermined one of illuminating areas 330a, 330b, 330c, 330d, 330e. For example, when the light source module 300 is applied in a headlight, the high beam (such as the laser sources 310a, 310e, 310d) is required to be turned off for illuminating approaching cars or pedestrians, and the low beam (such as the laser sources 310b, 310c) is turned on to illuminate the designated illuminating areas 330b, 330c, so as to ensure road traffic safety.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A laser diode packaging structure, comprising:
a lead frame which includes a frame body that has a front side and a back side opposite to said front side, a front circuit layer and a back circuit layer that are respectively disposed on said front and back sides, and an inner circuit layer that is disposed inside said frame body, said inner circuit layer including a first circuit connecting unit and a second circuit connecting unit, each of said first and second circuit connecting units having at least one first conductive via to electrically connect to said front circuit layer, and at least one second conductive via to electrically connect to said back circuit layer; and
at least one laser chip which is mounted on and electrically connected to said front circuit layer, and which is configured to emit a laser beam.

2. The laser diode packaging structure of claim 1, wherein for each of said first and second circuit connecting units, said second conductive via is farther to a geometric center of said inner circuit layer than said first conductive via.

3. The laser diode packaging structure of claim 1, wherein each of said first and second circuit connecting units has a terminal end portion and an extension portion extending away from said terminal end portion, said second conductive via being located at said terminal end portion, and said first conductive via being spaced apart from said second conductive via and being located at said extension portion.

4. The laser diode packaging structure of claim 1, wherein said inner circuit layer includes a plurality of said first circuit connecting units and a plurality of said second circuit connecting units.

5. The laser diode packaging structure of claim 4, wherein said front circuit layer includes at least two mounting units, each of said mounting units having a first region and a second region that are electrically isolated from each other, said first region being electrically connected to a respective one of said first circuit connecting units of said inner circuit layer, said second region being electrically connected to a respective one of said second circuit connecting units of said inner circuit layer.

6. The laser diode packaging structure of claim 4, wherein each of said first circuit connecting units includes a plurality of said first conductive vias that are electrically connected to different regions of said front circuit layer.

7. The laser diode packaging structure of claim 5, wherein each of said mounting units further includes a third region that is electrically isolated from said first region and said second region, and that is electrically connected to said first region through the respective one of said first circuit connecting units.

8. The laser diode packaging structure of claim 7, wherein for each of said mounting units, said first region has an area greater than a total area of said second region and said third region.

9. The laser diode packaging structure of claim 1, wherein said back circuit layer includes a plurality of back electrodes that are arranged on a peripheral region of said back side of said frame body.

10. The laser diode packaging structure of claim 9, wherein said back circuit layer includes a heat dissipating electrode that is disposed on a center region of said back side of said frame body distal from said peripheral region of said back side.

11. The laser diode packaging structure of claim 10, wherein said back electrodes are disposed on two opposite sides of said heat dissipating electrode.

12. The laser diode packaging structure of claim 9, which comprises a plurality of said laser chips, each of said laser chips being electrically connected to two of said first and second circuit connecting units and two of said back electrodes.

13. The laser diode packaging structure of claim 1, further comprising an optical element that is disposed on said front circuit layer of said lead frame and that is configured to direct the laser beam emitted from said laser chip.

14. The laser diode packaging structure of claim 13, which comprises a plurality of said laser chips, said optical element being mounted on a center region of said front circuit layer, said laser chips being mounted distal from said optical element.

15. The laser diode packaging structure of claim 13, wherein each of said first and second circuit connecting units of said inner circuit layer is located outside of a projection of said optical element on said inner circuit layer.

16. The laser diode packaging structure of claim 1, wherein said second conductive via of each of said first and second circuit connecting units is located at a peripheral region of said frame body.

17. The laser diode packaging structure of claim 1, wherein said frame body includes at least three edge portions, each of said first and second circuit connecting units including a terminal end portion that is adjacent to one of said at least three edge portions and an extension portion that extends from said terminal end portion towards another one of said at least three edge portions.

18. The laser diode packaging structure of claim 1, wherein said frame body of said lead frame is formed with a recess defined by a recess-defining wall, said recess-defining wall having a rectangular cross section, said laser chip being disposed in said recess and being located adjacent to a diagonal line of said rectangular cross section of said recess-defining wall.

19. The laser diode packaging structure of claim 18, wherein said laser chip is located at a diagonal line of said rectangular cross section of said recess-defining wall.

20. The laser diode packaging structure of claim 5, which comprises a plurality of said laser chips, each of said laser chips being disposed on said first region of a respective one of said mounting units.

21. The laser diode packaging structure of claim 20, wherein at least one of said mounting units further includes a third region that is electrically isolated from said first and second regions, and that is electrically connected to said first region through said inner circuit layer, said laser diode packaging structure further comprising at least one anti-electrostatic discharge element that is mounted on said third region of said at least one of said mounting units.

22. The laser diode packaging structure of claim 21, wherein each of said first circuit connecting units includes a plurality of said first conductive vias that are divided into two groups, said first and third regions of said at least one of said mounting units being electrically connected to one of said first circuit connecting units through a respective one of said two groups of said first conductive vias.

23. A light source module, comprising a laser diode packaging structure as claimed in claim 1.
